(19) United States
(12) Patent Application Publication
(10) Pub. No.: US 2017/0077164 A1
(43) Pub. Date: Mar. 16, 2017

(54) SOLID-STATE IMAGE SENSOR AND IMAGE PICKUP APPARATUS

(71) Applicant: CANON KABUSHIKI KAISHA, Tokyo (JP)

(72) Inventor: Kazunari Kawabata, Kawasaki-shi (JP)

(21) Appl. No.: 15/251,341

(22) Filed: Aug. 30, 2016

(30) Foreign Application Priority Data
Sep. 14, 2015 (JP) 2015-181035

(51) Int. Cl. H01L 27/146; H04N 5/378; H04N 5/225

(52) U.S. Cl. CPC H01L 27/14627; H04N 5/2254; H04N 5/378; H01L 27/14621; H01L 27/14625; H01L 27/14645

(57) ABSTRACT

A solid-state image sensor comprising a plurality of pixels including photoelectric conversion elements arranged in matrix and an microlens array in which a plurality of microlenses respectively corresponding to the plurality of pixels are arranged, wherein a first group including microlenses each having a first shape and a second group including microlenses each having a second shape different from the first shape are arranged in the microlens array, and a center of a region in which the microlenses constituting the first group is shifted from a center of an effective pixel region of the image sensor, and a region in which the microlenses constituting the second group are arranged includes two portions arranged to sandwich the entire first group.

### BACKGROUND OF THE INVENTION

Field of the Invention

The present invention relates to a solid-state image sensor and an image pickup apparatus.

Description of the Related Art

Light is incident on pixels arranged in an image sensor at different incident angles depending on the distances between the pixels and the center of the image sensor. This causes differences in the amounts of light incident on the photoelectric conversion elements of the pixels. Some image sensors have an optical path conversion element to compensate for the differences in the amounts of light. Japanese Patent Laid-Open No. 2006-528424 discloses a technique of arraying microlenses having light incident surfaces which differ in tilt depending on the distances between the center of an image sensor and pixels.

If the internal structure of an image sensor is asymmetrical with respect to the center of each pixel, optical characteristics in the image sensor become asymmetrical. This situation will be described with reference to FIGS. 8A to 8D. A sensor chip 801 has pixels arrayed in matrix. Pixels 802, 803, and 804 arranged side by side in a direction along the rows of the sensor chip 801 will be exemplarily described. The pixel 803 is provided at the intersection point between diagonal lines indicted by dashed lines in the sensor chip. The intersection point between the diagonal lines corresponds to a center C of the sensor chip. The pixels 802 and 804 sandwich the pixel 803. The pixels 802 and 804 are selected such that a distance d1 from the pixel 802 to the pixel 803 is equal to a distance d2 from the pixel 803 to the pixel 804. As shown in FIG. 8C, a microlens 109 having a symmetrical shape is arranged on the pixel 803. In this case, the “symmetrical shape” indicates a shape symmetrical with respect to a straight line as a center axis which is perpendicular to the bottom surface of the microlens and extending from the bottom surface and passing through the highest position of the microlens. In addition, as shown in FIGS. 8B and 8D, microlenses having the same shape are laterally inverted and arranged on the pixels 802 and 804. The microlenses arranged on the pixels 802 and 804 are called microlenses having asymmetrical shapes. In this case, the “asymmetrical shapes” each indicate a shape asymmetrical with respect to a straight line as a center axis which is perpendicular to the bottom surface of the microlens and extending from the bottom surface and passing through the highest position of the microlens. Since the pixels 802 and 804 are equidistant from the center C of the sensor chip, light beams are incident on the respective pixels at the same tilt angle.

In this case, the sectional structure of some pixel has an asymmetrical shape with respect to the center of a photoelectric conversion element 105 because of the presence of a gate electrode 106 of a transistor arranged in the pixel. For this reason, as shown in FIG. 8B, in the pixel 802, the gate electrode 106 interferes with incident light to cause a loss in light incident on the photoelectric conversion element 105, whereas in the pixel 804, no loss occurs in incident light. This makes the pixels 802 and 804 have uneven sensitivity. As a consequence, the sensor chip 801 has laterally asymmetrical luminance shading. In other words, the asymmetry of the internal layout of each pixel makes the sensor chip have asymmetrical optical characteristics. In addition, differences in sensitivity occur in the peripheral portion of the sensor chip. Furthermore, a high refractive index material such as polysilicon is generally used for the gate electrode 106. For this reason, the gate electrode 106 is directly irradiated with light, the light is greatly refracted toward adjacent pixels to cause mixture of colors, resulting in a deterioration in image quality.

### SUMMARY OF THE INVENTION

One aspect of the present invention provides a solid-state image sensor comprising a plurality of pixels including photoelectric conversion elements arranged in matrix and an microlens array in which a plurality of microlenses respectively corresponding to the plurality of pixels are arranged, wherein a first group including microlenses each having a first shape and a second group including microlenses each having a second shape different from the first shape are arranged in the microlens array, and a center of a region in which the microlenses constituting the first group is shifted from a center of an effective pixel region of the image sensor, and a region in which the microlenses constituting the second group are arranged includes two portions arranged to sandwich the entire first group.

Further features of the present invention will become apparent from the following description of exemplary embodiments with reference to the attached drawings.

### BRIEF DESCRIPTION OF THE DRAWINGS

FIGS. 1A to 1D are schematic views for explaining the first embodiment;

FIGS. 2A and 2B are schematic views showing the arrangement of pixels used in this embodiment;

FIGS. 3A and 3B are schematic views showing an example of a microlens used in this embodiment;

FIGS. 4A to 4C are schematic views showing another example of a microlens used in this embodiment;

FIGS. 5A to 5D are schematic views for explaining the second embodiment;

FIGS. 6A to 6D are schematic views for explaining the third embodiment;

FIGS. 7A to 7D are schematic views for explaining the fourth embodiment;

FIGS. 8A to 8D are schematic views for explaining a problem in a conventional solid-state image sensor; and

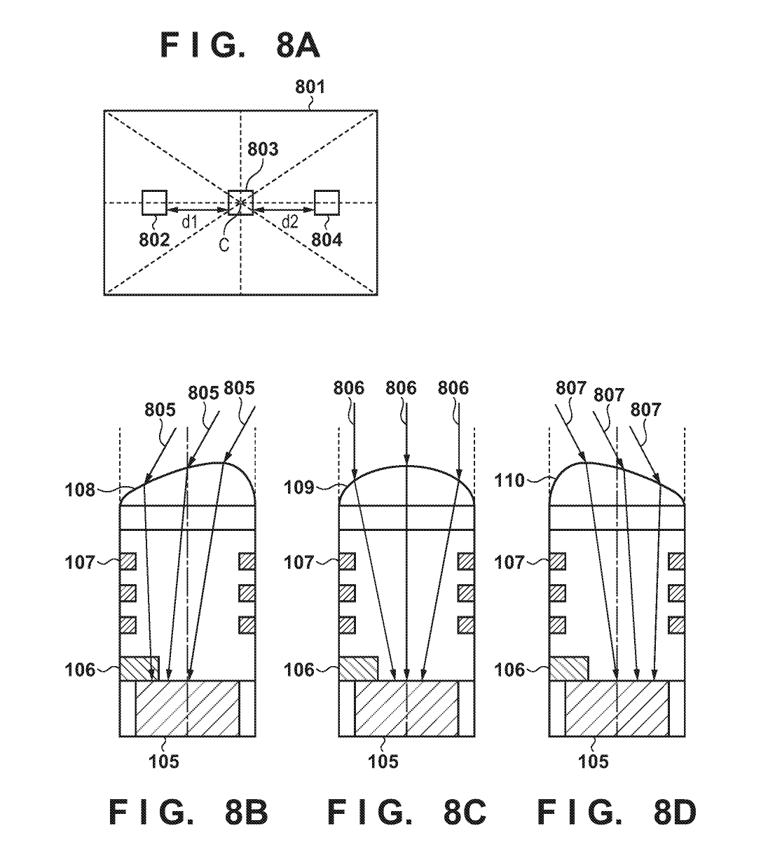

FIG. 9 is a block diagram of an image pickup apparatus.

### DESCRIPTION OF THE EMBODIMENTS

Microlenses for a solid-state image sensor according to each embodiment are used, for example, for a CMOS image sensor as a solid-state image sensor. A CMOS image sensor has many pixels arranged in a flat light-receiving region of a sensor chip. Color filters are formed on the upper portions of the light-receiving units (photoelectric conversion elements) of the respective pixels. According to the general structure of the CMOS image sensor, optical elements (microlenses) are arranged on the upper portion of the color filters. It is possible to generate a color image by obtaining luminance signals corresponding to the respective colors, namely, red (R), green (G), and blue (B), through the respective color filters. A solid-state image sensor according to the present invention includes microlenses each having an asymmetrical shape suitable for light which is incident while greatly tilting obliquely with respect to the light-receiving surface of the sensor chip. An embodiment of a microlens according to the present invention will be described below.

### First Embodiment

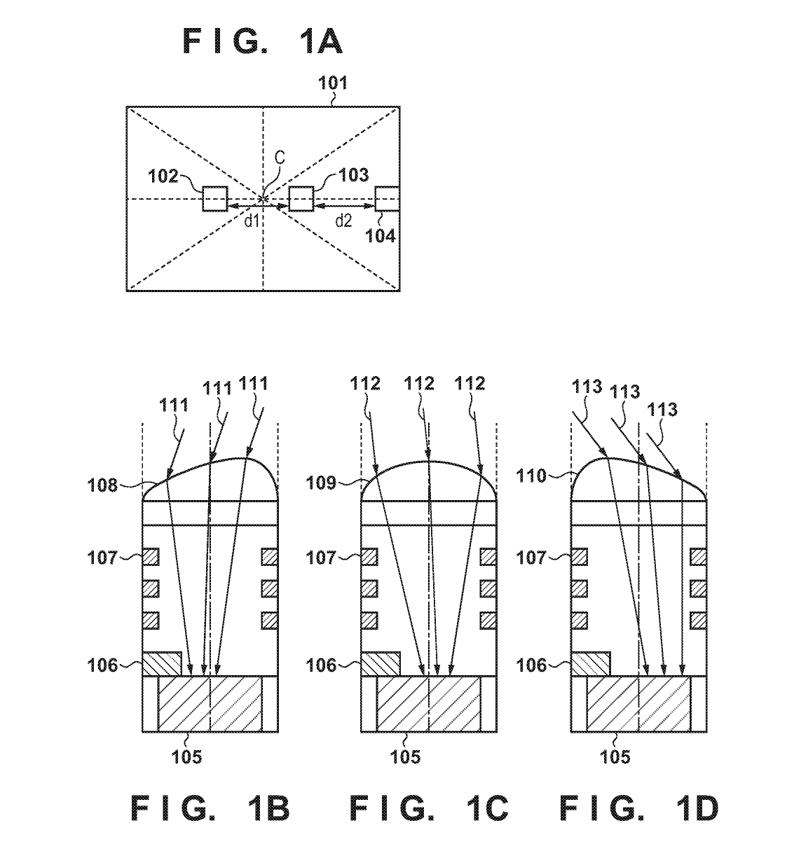

The first embodiment of the present invention will be described with reference to FIGS. 1A to 1D. FIGS. 1A to 1D show the arrangement of pixels and the sectional structures of pixels according to this embodiment. A sensor chip 101 has many pixels arranged in matrix. FIG. 1A shows pixels 102, 103, and 104 included in the sensor chip. Pixels arrayed along a row in the sensor chip are arrayed in the lateral direction in FIG. 1A. The pixels 102, 103, and 104 are arranged on a straight line passing through the middle of the sensor chip 101 and extending along a row. The intersection point between diagonal lines indicated by dashed lines in the sensor chip 101 is a center C of the effective pixel region of the sensor chip 101. In the following description, the center C of the sensor chip 101 indicates the center of the effective pixel region of the sensor chip 101. In this embodiment, the pixel 103 on which a microlens having a symmetrical shape is arranged can be provided at a position different from the center C of the sensor chip. A distance d1 from the pixel 102 to the pixel 103 is equal to a distance d2 from the pixel 103 to the pixel 104. Microlenses 108 and 110 having asymmetrical shapes are respectively arranged on the pixel 102 and the pixel 104.

FIGS. 1B, 1C, and 1D respectively show the sectional structures of the pixels 102, 103, and 104. The sectional views shown in FIGS. 1B, 1C, and 1D respectively correspond to the sections of the pixels 102, 103, and 104. In this case, the “sections” indicate sections obtained when assuming that the pixels 102, 103, and 104 are cut by a plane which passes through the centers of the pixels 102 and 104 and is perpendicular to the sensor chip 101. In this case, the center of each pixel may be the intersection point between diagonal lines of the pixel in a planar view, the center of each region where photoelectric conversion elements (to be described later) are arranged, or the barycenter of a planar shape of each pixel when seen in a planar view. Each sectional view shows one of the microlenses 108, 109, and 110, a wiring layer 107, a gate electrode 106 of a transistor, and a photoelectric conversion element 105. The sectional structure of each pixel has a structure asymmetrical with respect to the lateral direction of the pixel because of the presence of the gate electrode 106 of the transistor when seen in the lateral direction of the sensor chip shown in FIG. 1A.

As shown in FIG. 1C, a microlens 109 having a shape symmetrical with respect to the center axis is arranged on the pixel 103. Assume that the “center axis” in this case is a straight line extending from the highest portion (vertex) of the microlens to the bottom surface of the microlens. The microlenses 108 and 110, each having a vertex shifted toward the pixel 103 and a shape asymmetrical with respect to the center axis, are respectively arranged on the pixels 102 and 104. Letting a microlens have an asymmetrical shape makes it possible to refract light incident with a large tilt on the light-receiving surface in a peripheral portion of the sensor chip in the direction of the photoelectric conversion element 105. This can achieve an improvement in light collection efficiency.

In this embodiment, the microlenses 108 and 110 having the same shape are arranged on the pixels 102 and 104 so as to be laterally inverted with respect to a straight line passing through the center of the pixel 103 and extending along a pixel column. Assume that the distances from the vertex of the microlens 109 to the vertices of the microlenses 108 and 110, which are spaced apart from it to the left and the right in the horizontal direction, are equal to each other. The distance from the center C of the sensor chip 101 to the pixel 102 is shorter than the distance from the center C of the sensor chip 101 to the pixel 104. The microlenses 108 and 110 having asymmetrical, identical shapes are arranged on the pixels 102 and 104 located at positions laterally symmetrical with respect to the pixel 103. In comparison between the microlenses having the asymmetrical shapes, the pixel, of the pixels laterally equidistant from the pixel 103, which is located on the left side can refract light more than the microlens located on the right side. That is, the microlens arranged on the pixel 102 can refract light more than the microlens arranged on the pixel at a symmetrical position of the pixel 102 with respect to the middle of the sensor chip 101.

Microlenses arranged in correspondence with a plurality of pixels will be referred to as a microlens array as a whole. According to the above description, one microlens 109 having a symmetrical shape is arranged in a microlens array. However, the present invention is not limited to a case in which the microlens 109 having the symmetrical shape is arranged on only one specific pixel. Since the tilt of the optical axis is small in the middle portion of the sensor chip 101, a plurality of microlenses having symmetrical shapes may be collectively arranged as a group. An effect similar to that described above can be obtained even by arranging microlenses having symmetrical shapes on a plurality of pixels around the pixel 103. That is, in this case, a group of microlenses having asymmetrical shapes is arranged around a group of microlenses having symmetrical shapes.

In this embodiment, the center of the group of the microlenses having the symmetrical shapes does not coincide with the center C of the sensor chip 101, and their centers are shifted from each other. That is, microlenses having symmetrical shapes can be arranged on pixels located in a predetermined range centered on a pixel at a position shifted from the center C of the sensor chip 101. Microlenses having asymmetrical shapes are arranged on pixels located outside the range. The asymmetrical microlenses are arranged such that their regions sandwich the entire region of the symmetrical microlenses.

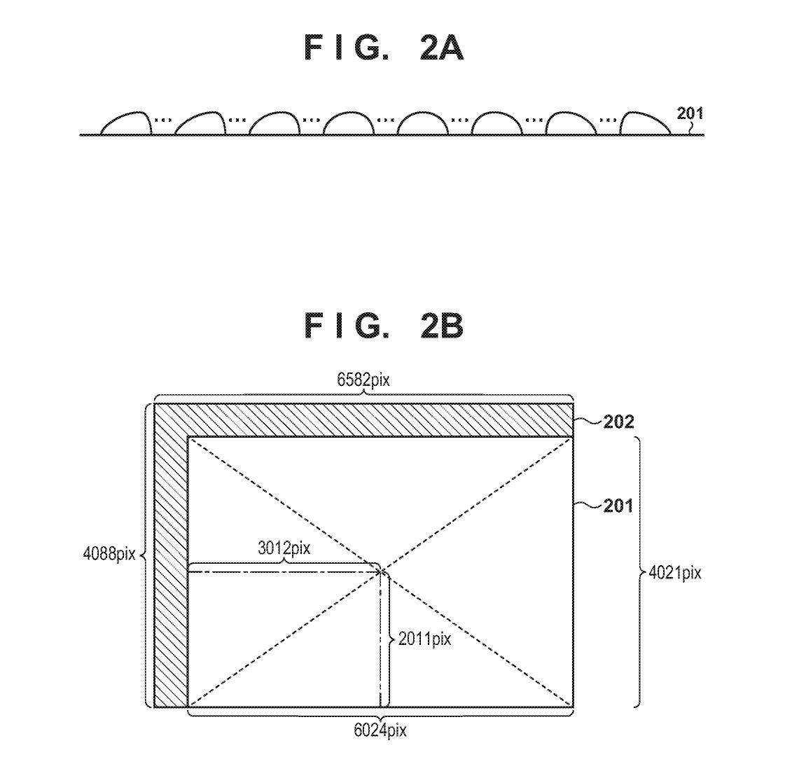

The shapes of microlenses may be changed to improve the light collection efficiency in accordance with the distances from the pixel 103 on which the microlens 109 having the symmetrical shape is arranged. Microlenses having asymmetrical shapes may be shaped to refract obliquely incident light more as they are arranged closer to the periphery. That is, referring to FIG. 1A, in comparison between the microlenses laterally equidistant from the middle of the sensor chip 101, the microlens on the left side is shaped to refract light more than the microlens on the right side. FIG. 2A shows this state. The microlenses are shaped such that the upper surfaces of the microlenses tilt more from the middle to the peripheral portions so as to refract incident light at angles closer to the vertical. The highest positions of the microlenses 108 and 110 having the asymmetrical shapes from their bottom surfaces are shifted from the centers of the bottom surfaces of the respective microlenses with increases in distance from the microlens 109. When microlenses having asymmetrical shapes differ in their shapes depending on the positions on the sensor chip, microlenses having asymmetrical shapes laterally equidistant from the center C may differ in their shapes. In comparison with pixels on which microlenses having asymmetrical shapes are arranged, lenses having different shapes are arranged on two pixels equidistant from the center C of the sensor chip 101. In other words, the shapes of microlenses having asymmetrical shapes are changed such that the positions of the highest portions of the microlenses are shifted in accordance with the distances from the center of a group of microlenses having symmetrical shapes.

FIGS. 1B to 1D schematically show incident light 111, incident light 112, and incident light 113 which are incident on the respective pixels. Since the pixels 102 and 104 are located at different distances from the center C of the sensor chip, light is incident on the respective pixels at different angles. More specifically, light with a smaller tilt than that of light incident on the pixel 104 is incident on the pixel 102. However, the microlenses 108 and 110 having the asymmetrical, identical shapes are arranged on the pixels 102 and 104. For this reason, the microlens on the pixel 102 closer to the center C of the sensor chip 101 than the pixel 104 refracts light more and can make the light incident on the photoelectric conversion element 105 so as to avoid the gate electrode 106.

In this embodiment, even if the pixel 102 has an asymmetrical sectional structure, the gate electrode 106 is not directly irradiated with light refracted by the pixel 102. In addition, a given pixel closer to the periphery than the pixel 102 has, on it, a microlens whose lens surface tilts more than that of the microlens 108 arranged on the pixel 102. That is, the microlens on the peripheral side has a shape that can refract incident light with a large tilt in the direction of the photoelectric conversion element 105. This makes it possible to prevent the gate electrode 106 from being irradiated with light even in a peripheral portion of the sensor chip 101.

Arranging microlens arrays in this manner makes it possible to reduce unevenness in the distribution of sensitivity on the entire surface of the sensor chip 101. According to the above description, the center C of the sensor chip is set as the center of the effective pixel region. However, the effect of this embodiment is not limited to this arrangement. More specifically, light with which the sensor surface is irradiated generally changes in angle in a radiation direction centered on the optical axis of the imaging lens of a camera. For this reason, the optical axis of the imaging lens can coincide with the position of a pixel in the center of the sensor chip on which a microlens having a symmetrical shape is arranged. However, since a light beam undergoes only a small change in angle near the optical axis, the optical axis may approximately coincide with the center C of the sensor chip. It is possible to adjust the arrangement of microlenses having symmetrical and asymmetrical shapes, as needed, in accordance with the arrangement of peripheral circuits of the sensor chip or the arrangement of OB (Optical Black) pixels and the like.

A sensor chip with a total pixel count of 6582 (horizontal)×4088 (vertical) will be described as a specific example of a sensor chip with reference to FIG. 2B. The hatched portion is a region for OB (Optical Black) pixels and NULL pixels. In this case, the sensor chip has an effective pixel count of 6024 (horizontal)×4021 (vertical). The central pixel of an effective pixel region 201 is located at the position shifted from the pixel at the lower left end of the effective pixel region 201 to the right by 3,012 pixels and also shifted upward by 2,011 pixels. This pixel is defined as the pixel arranged in the middle of the sensor chip. Since the number of pixels by which the position is shifted in the vertical direction is odd, the median of the pixel count can be defined as the pixel at the position moved upward by 2,011 pixels. As in this case, when the pixel count in the horizontal direction is even, it is possible to change, as needed, which one of the two pixel candidates equidistant from the end portions of the sensor chip is to be used, depending on definitions.

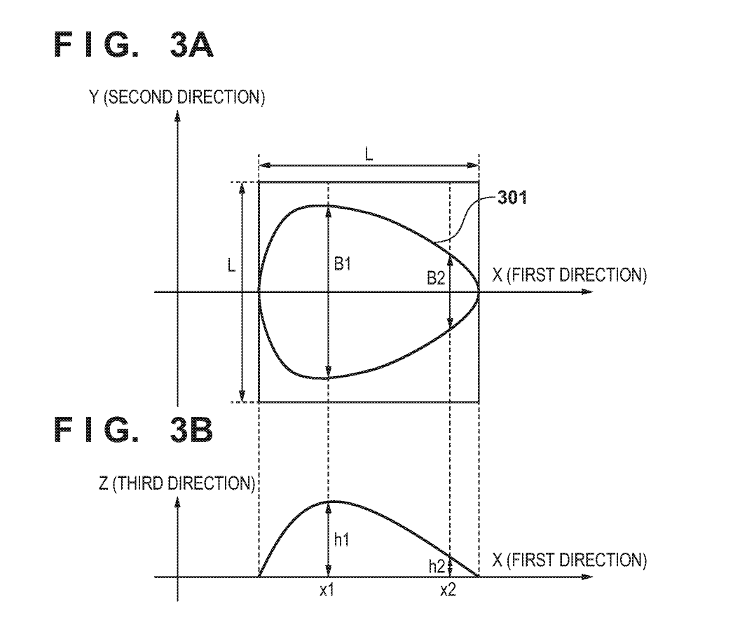

This embodiment can use, as each pixel in a peripheral portion of the sensor chip, a microlens 301 having a teardrop shape like that shown in FIG. 3A or 3B, which is a microlens having an asymmetrical shape. Referring to FIGS. 3A and 3B, L represents the length of each side of a pixel, and the first to third directions in the following description are defined as follows: the first direction is a direction from the middle of the sensor chip to the periphery; the second direction is a direction perpendicular to the first direction within the bottom surface of the microlens 301; and the third direction is a direction perpendicular to the first and second directions. FIG. 3A is a schematic view of the bottom surface shape of the microlens 301. FIG. 3B is a schematic view showing the sectional shape of the microlens 301 along a plane defined by the first and third directions.

As shown in FIG. 3B, the height of the microlens 301 gradually decreases, within one pixel, in the first direction from the center of the sensor chip to the periphery. The relation between heights h1 and h2 shown in FIGS. 3A and 3B is expressed as h1>h2, where h1 is the height of the microlens at a position x1 and h2 is the height of the microlens at a position x2. In addition, as shown in FIG. 3A, the microlens 301 has a shape whose width gradually decreases in the second direction. The relation between widths B1 and B2 is expressed as B1>B2, where B1 is the width of the microlens at the position x1 and B2 is the width of the microlens at the position x2. When using the microlens 301, it is possible to gradually change the tilt of the lens toward the periphery of the sensor chip so as to refract light more, as shown in FIG. 2A.

Letting a microlens have such a shape can refract light incident with a large tilt on a pixel in a peripheral portion of the sensor chip in the direction of the photoelectric conversion element 105, thereby obtaining high sensitivity. This makes it possible to obtain high sensitivity while improving optical asymmetry in the sensor chip overall.

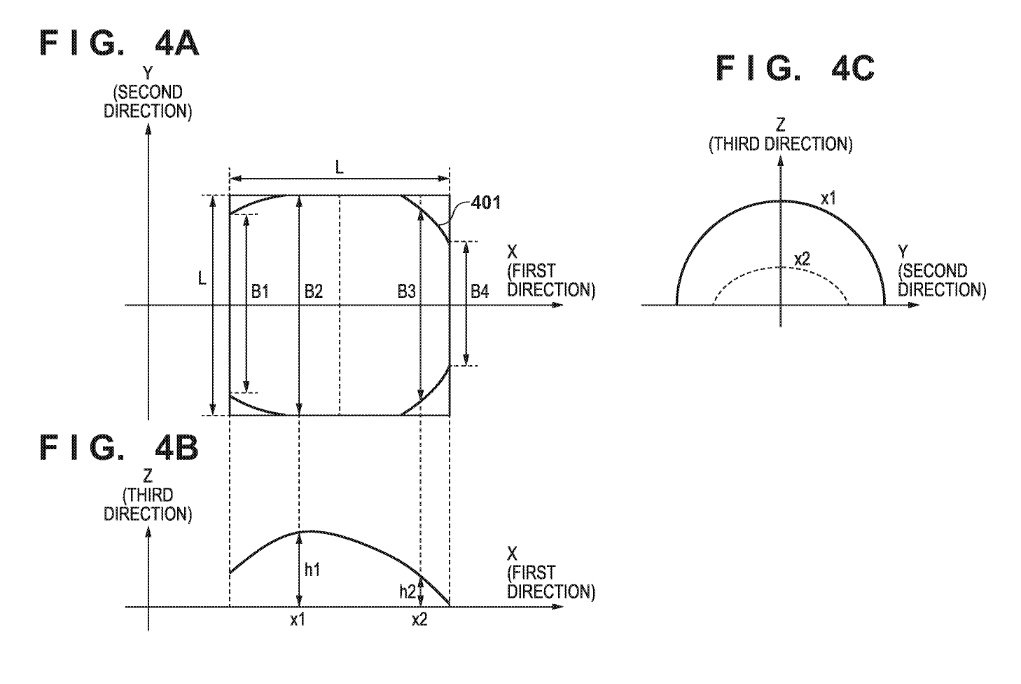

In addition, a microlens 401 shown in FIGS. 4A to 4C may be used as another example of a microlens having an asymmetrical shape. As shown in FIG. 4A, the microlens 401 occupies a larger area in one pixel than the microlens 301. Like the microlens 301, the microlens 401 gradually decreases in height in the first direction from the middle of the sensor chip to the periphery. As shown in FIG. 4A, this microlens has a shape whose width gradually changes in the second direction. A width B1 of an end portion of the microlens which is located on the side close to the middle of the sensor chip is larger than a width B4 of an end portion of the microlens which is located on the peripheral side. That is, the width B1 of the end portion on the side close to the symmetrical microlens 109 is larger than the width B4 of the end portion on the side far from the microlens 109. This microlens gradually increases in width in the second direction from the width B1 of one end portion to a largest width B2. Thereafter, the width of the microlens keeps at the predetermined width B2 and then gradually decreases to the width B4 of the other end portion through a width B3. In this case, the end portions of the microlens correspond to the boundary portions with respect to adjacent microlenses when the microlenses are arranged adjacent to each other, and are portions at each of which the height decreases most after a gradual decrease in height from the largest height. Alternatively, the end portions are portions corresponding to the right and left sides of the pixel in the first direction, which are indicated by “L×L” in FIG. 4A. FIG. 4C shows a section of the microlens 401 along the second direction. The microlens 401 features to gradually increase, within one pixel, in the curvature radius of the upper surface from a highest place x1 to the periphery of the sensor chip. In other words, the radius curvature of the upper surface of the microlens gradually increases toward an end portion in a direction opposite to the center of a region where a group of symmetrical microlenses is arranged. That is, referring to FIG. 4C, the curvature radius of the upper surface of the microlens at a position x2 is larger than that of the microlens at a position x1. Using such a shape can obtain higher sensitivity while improving asymmetry in a peripheral portion of the sensor chip. When using this lens, it is possible to change the tilt of the lens to refract light more toward the periphery of the sensor chip as shown in FIG. 2A.

In addition, this embodiment has exemplified the case in which the gate electrode 106 of the transistor is a factor that causes optical asymmetry in the sensor chip. However, the present invention is not limited to this. Similar optical asymmetry is sometimes caused by other factors such as a wiring layer in the pixel, an impurity distribution in the photoelectric conversion element, an impurity layer for separation between the photoelectric conversion elements of the adjacent pixels, and the shape of the photoelectric conversion element. Even with these factors to consider, the same effects as those described above can be obtained by adjusting the incident angle of light with respect to each photoelectric conversion element by using the microlens.

### Second Embodiment

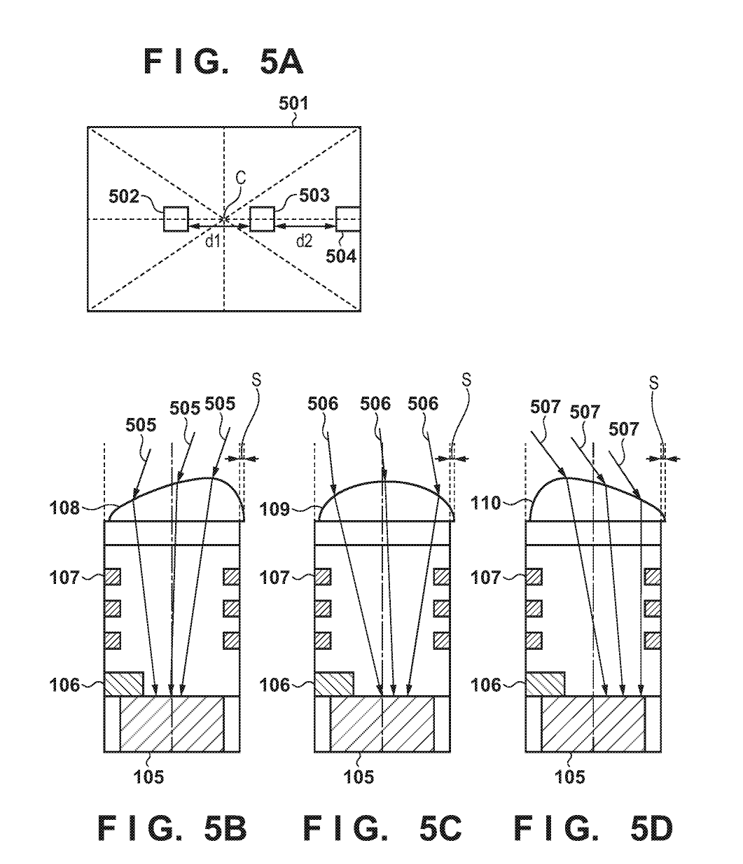

The second embodiment of the present invention and its effects will be described with reference to FIGS. 5A to 5D. Unlike the first embodiment, the second embodiment features in that the centers of microlenses respectively having symmetrical and asymmetrical shapes are located at positions shifted from the centers of the photoelectric conversion elements of the corresponding pixels which are provided in correspondence with the respective microlenses. In this case, the “centers of the photoelectric conversion elements” each indicate the center or barycenter of a n-type region of a p-n junction photodiode when the n-type region is seen in a planar view, if the photodiode is of a type designed to store electrons in accordance with light. Alternatively, the center of each photoelectric conversion element may be the barycenter of the photoelectric conversion element when seen in a planar view, or the center or barycenter of the p-type region if the photodiode is of a type designed to store holes in accordance with light.

FIGS. 5A to 5D show the arrangement of pixels and the sectional structures of the respective pixels. Many pixels are arranged in matrix in a sensor chip 501. The pixels include pixels 502, 503, and 504. Referring to FIG. 5A, the intersection point between diagonal lines indicated by dashed lines in the sensor chip is a center C of the effective pixel region of the sensor chip. In this case, the pixel 503 is provided at a position different from the center C. The pixels 502 and 504 are selected such that a distance d1 from the pixel 502 to the pixel 503 is equal to a distance d2 from the pixel 503 to the pixel 504.

FIGS. 5B, 5C, and 5D are respectively sectional views of the pixels 502, 503, and 504. As shown in FIGS. 5B, 5C, and 5D, the centers of microlenses 108, 109, and 110 arranged in correspondence with the respective pixels are shifted from the centers of the respective photoelectric conversion elements to the right by a shift amount S. In this manner, the asymmetry of each pixel is adjusted by shifting the arrangement position of the microlens as well as changing the shape of the microlens. This can adjust the position at which light incident on the photoelectric conversion element 105 is focused, and hence improves a deterioration in image quality caused by the asymmetry of the structure of each pixel. This embodiment can also use microlenses having the shapes shown in FIGS. 3A and 3B or FIGS. 4A to 4C. The center of the bottom surface of the microlens 109 having a symmetrical shape may coincide with the center axis. The position of the center of the bottom surface of an asymmetrical microlens may coincide with the center between the end portions of the section of the microlens 108 in FIG. 5B or the center between the end portions of the section of the pixel 110 in FIG. 5D. Alternatively, the center of the bottom surface of a microlens may coincide with the position of the center of the distance from one end of the bottom surface of the microlens to the other end, assuming that the microlens is cut along a straight line in a first direction passing through the center of the width of the microlens measured in a second direction shown in FIGS. 3A and 3B and FIGS. 4A to 4C. Alternatively, the center of the bottom surface of a microlens may coincide with the center between one end and the other end of the bottom surface of the microlens when measured in the first direction perpendicular to the center of the maximum width of the microlens in the second direction, or may coincide with the position of the barycenter of the planar shape of the bottom surface of the microlens. This embodiment is not either limited to a case in which the microlens 109 having the symmetrical shape is arranged on only one specific pixel. Since the tilt of the optical axis is small in the middle portion of the sensor chip 501, a plurality of microlenses having symmetrical shapes may be collectively arranged as a group.

### Third Embodiment

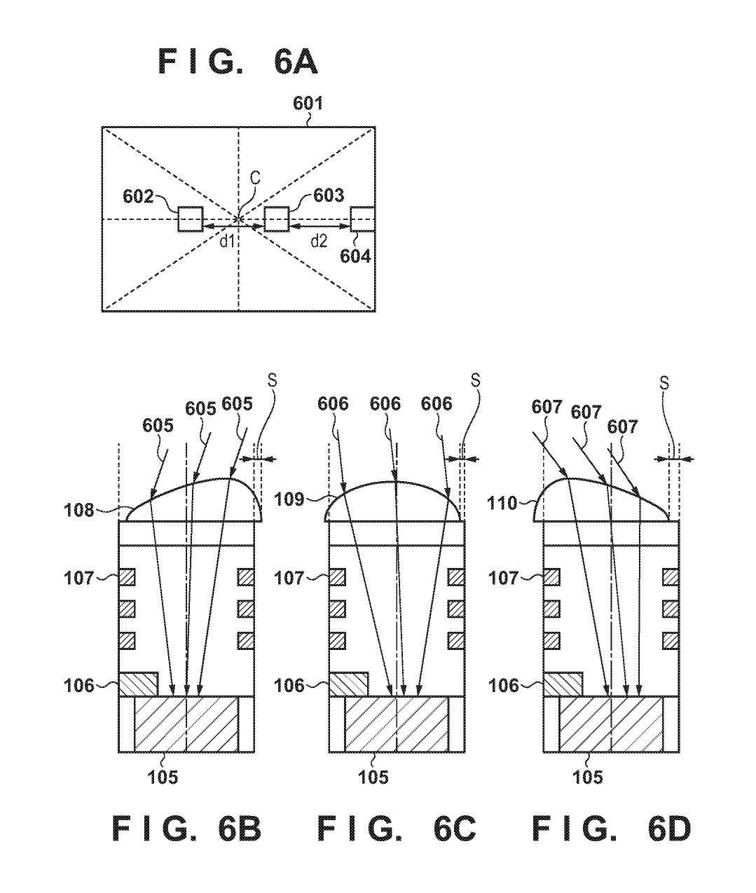

The third embodiment of the present invention and its effects will be described with reference to FIGS. 6A to 6D. A description redundant to other embodiments will be omitted. This embodiment features in that the shift amounts of microlenses with respect to the centers of the photoelectric conversion elements of the pixels provided in correspondence with the microlenses differ depending on the positions of the microlenses.

FIGS. 6A to 6D show the arrangement of pixels and the sectional structures of the respective pixels. Many pixels are arranged in matrix in a sensor chip 601. The pixels include pixels 602, 603, and 604. Referring to FIG. 6A, the intersection point between diagonal lines indicated by dashed lines is a center C of the effective pixel region of the sensor chip. The pixel 603 is provided at a position different from the center C. The pixels 602 and 604 are selected such that a distance d1 from the pixel 602 to the pixel 603 is equal to a distance d2 from the pixel 603 to the pixel 604. FIGS. 6B, 6C, and 6D are respectively sectional views of the pixels 602, 603, and 604. As shown in FIGS. 6B, 6C, and 6D, microlenses 108, 109, and 110 each are arranged so as to be shifted in a direction from the center of the photoelectric conversion element to the center of the sensor chip. Shift amounts S gradually increase toward a peripheral portion of the sensor chip.

In this manner, since the position at which light is focused on a photoelectric conversion element 105 can be adjusted by adjusting the asymmetry of a pixel by not only changing the shape of the microlens but also adjusting the arrangement position of the microlens array, high sensitivity can be obtained. In this case, the shift amount S of each microlens from the center of the photoelectric conversion element may be adjusted as needed in accordance with the exit pupil distance of the imaging lens or F-value.

More specifically, when using a lens with a long exit pupil distance, a light beam with a small tilt is incident on a pixel in a peripheral portion of the sensor chip like a pixel in the middle portion of the sensor chip. For this reason, the shift amount of the microlens from the center of the photoelectric conversion element can be set to be small. When using an imaging lens with a short exit pupil distance, a light beam with a large tilt is incident on a pixel in a peripheral portion of the sensor chip. For this reason, the shift amount of the microlens with respect to the center of the photoelectric conversion element can be set to be large. This can suppress sensitivity unevenness in a lens with a short exit pupil distance that allows a large amount of oblique incident light. In addition, this embodiment can also use microlenses having the shapes shown in FIGS. 3A and 3B and FIGS. 4A to 4C.

### Fourth Embodiment

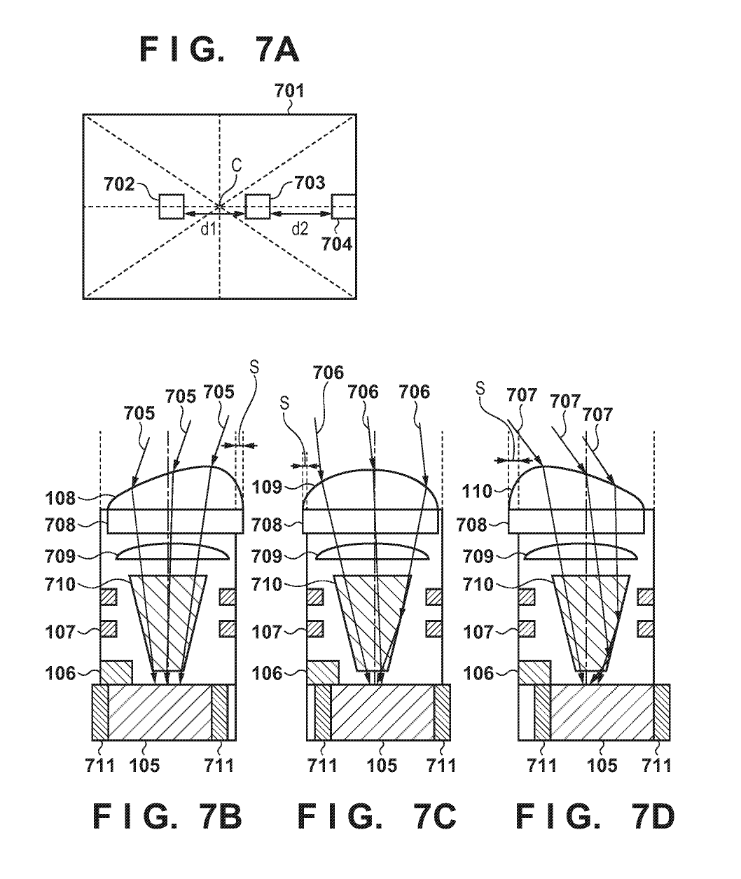

The fourth embodiment of the present invention and its effects will be described with reference to FIGS. 7A to 7D. A description redundant to other embodiments will be omitted. FIGS. 7A to 7D show the arrangement of pixels and the sectional structures of the respective pixels. Many pixels are arranged in matrix in a sensor chip 701. The pixels include pixels 702, 703, and 704. Referring to FIG. 7A, the intersection point between diagonal lines indicated by dashed lines is a center C of the effective pixel region of the sensor chip. The pixel 703 is provided at a position different from the center C. The pixels 702 and 704 are selected such that a distance d1 from the pixel 702 to the pixel 703 is equal to a distance d2 from the pixel 703 to the pixel 704. FIGS. 7B, 7C, and 7D are respectively sectional views of the pixels 702, 703, and 704. As shown in FIGS. 7B, 7C, and 7D, microlenses 108, 109, and 110 each are arranged so as to be shifted in a direction from the center of the photoelectric conversion element to the center of the sensor chip. Shift amounts S gradually increase toward a peripheral portion of the sensor chip.

Unlike the first to third embodiments, the fourth embodiment features in that other components constituting each pixel are also arranged so as to be shifted from the center of the photoelectric conversion element. The other components include a color filter 708, an interlayer lens 709, a lightguide 710, and a pixel separation structure 711.

The color filter 708 transmits light with a wavelength corresponding to the color of each pixel, for example, R, G, or B, and absorbs light with other wavelengths, thus having a color separation function. The interlayer lens 709 has both a function of increasing the amount of light received by a photoelectric conversion element 105 by condensing light incident on a pixel boundary portion onto the middle of the pixel and a function of reducing mixture of colors into adjacent pixels. In general, a silicon nitride or the like which is a high refractive material is used for the lightguide 710. This produces an effect of confining light within the lightguide. The lightguide 710 therefore has a function of implementing high sensitivity by reducing light leaking to portions other than the photoelectric conversion element 105 and a function of guiding incident light with a large tilt toward the photoelectric conversion element 105 by reflecting it by the side surface of the lightguide 710.

The pixel separation structure 711 is formed in a silicon substrate in which the photoelectric conversion element 105 is provided. The pixel separation structure is a structure in which polysilicon is embedded in a trench formed in a silicon substrate or a structure in which the surrounding of the silicon substrate is covered by a silicon oxide film. The pixel separation structure is often formed from a metal embedded in a trench, and has a function of reducing mixture of colors of light and electric charge within the silicon and increasing the number of saturated electrons in the pixel. Although the above components have been exemplified, any components having different names may be used as long as they have similar functions.

Each component is shifted so as to increase the efficiency of guiding light to the photoelectric conversion element 105. In this embodiment, the microlenses 108, 109, and 110, the color filter 708, and the interlayer lens 709 are shifted in the same direction as that in which each microlens is shifted in the third embodiment. In addition, the lightguide 710 and the pixel separation structure 711 are shifted in a direction opposite to the microlens, that is, toward a peripheral portion of the sensor chip in FIGS. 7A to 7D. Using such an arrangement makes it possible to obtain high sensitivity while preventing mixture of colors into adjacent pixels.

In this embodiment, the centers of the microlens, the interlayer lens, and the color filter are shifted from the center of the lightguide. In this case, the centers of the interlayer lens, the color filter, and the lightguide can be the barycenters of orthographic projection views obtained by orthographic projection of these components onto the surface of the sensor chip or the bottom surface of the microlens array. If an orthographic projection view of the interlayer lens is a circle, the center of the circle can be set as the center of the interlayer lens. If the color filter is rectangular, the intersection point between diagonal lines may be set as the center of the filter.

In addition, the same effects as those described above can be obtained even if the gate electrode 106, the isolation structure between color filters, a light-shielding layer provided between adjacent pixels, and the like are arranged as components other than the above components so as to be shifted.

In addition, since the same effects as those described above can be obtained concerning a pixel using all the components described above and a pixel using some of them, the present invention is not limited to the arrangement of this embodiment. Furthermore, the embodiment can use, as microlenses, microlenses having the same shapes as those shown in FIGS. 3A and 3B and FIGS. 4A to 4C.

### Fifth Embodiment

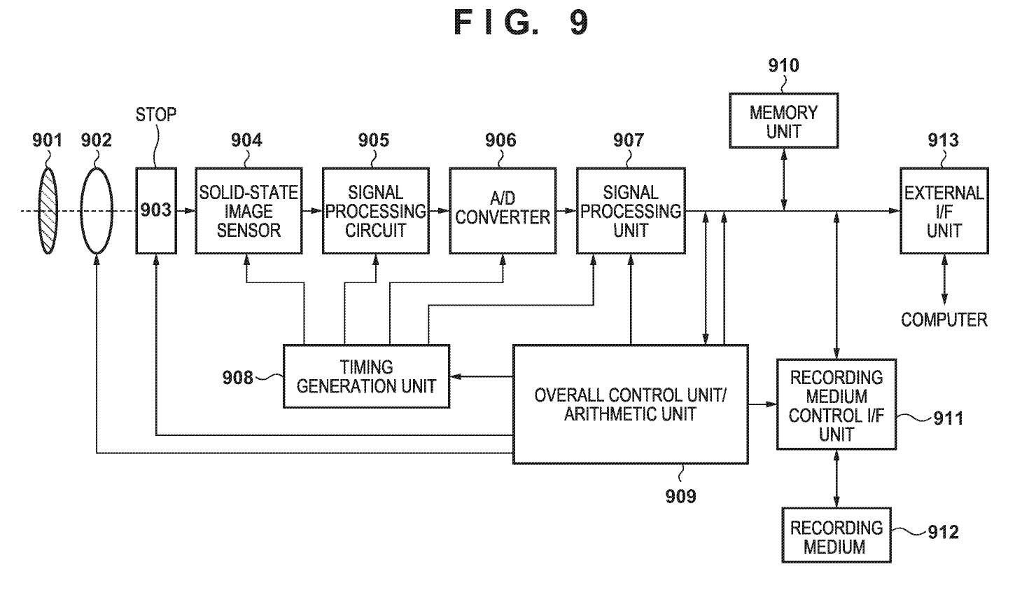

A case in which a solid-state image sensor according to the present invention is applied to an image pickup apparatus will be described with reference to FIG. 9. An optical system includes an imaging lens 902, a shutter 901, and an aperture 903, and forms an image of an object onto a solid-state image sensor 904. A signal processing circuit 905 processes an output signal from the solid-state image sensor 904. An A/D converter 906 converts the signal from an analog signal to a digital signal. A signal processing unit 907 further arithmetically processes the output digital signal. The processed digital signal is stored in a memory unit 910 or sent to an external device such as a computer via an external I/F unit 913. A timing generation unit 908 controls the solid-state image sensor 904, the signal processing circuit 905, the A/D converter 906, and the signal processing unit 907. In addition, an overall control unit/arithmetic unit 909 controls the system overall. In order to record an image on a recording medium 912, the output digital signal is recorded via a recording medium control I/F unit 911 which is controlled by the overall control unit/arithmetic unit.

Although the above embodiment has exemplified the front-side illumination solid-state image sensor, the present invention can also be applied to a back-side illumination solid-state image sensor. Likewise, the present invention can also be applied to a photoelectric conversion film solid-state image sensor.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-181035, filed Sep. 14, 2015, which is hereby incorporated by reference herein in its entirety.

What is claimed is:

1. A solid-state image sensor comprising a plurality of pixels including photoelectric conversion elements arranged in matrix and an microlens array in which a plurality of microlenses respectively corresponding to the plurality of pixels are arranged,
wherein a first group including microlenses each having a first shape and a second group including microlenses each having a second shape different from the first shape are arranged in the microlens array, and
a center of a region in which the microlenses constituting the first group is shifted from a center of an effective pixel region of the image sensor, and a region in which the microlenses constituting the second group are arranged includes two portions arranged to sandwich the entire first group.

2. The sensor according to claim 1, wherein when a straight line which is perpendicular to a bottom surface of a microlens and passes through a highest position from the bottom surface is set as a center axis, the microlens having the first shape has a symmetrical shape with respect to the center axis, and the microlens having the second shape has an asymmetrical shape with respect to the center axis.

3. The sensor according to claim 1, wherein a height of the microlens having the second shape from a bottom surface becomes maximum on a side closer to a center of the region in which the microlenses constituting the first group are arranged than a center of the bottom surface of the microlens having the second shape.

4. The sensor according to claim 3, wherein a curvature radius of an upper surface of the microlens having the second shape increases from a place where the height from the bottom surface is maximum in a direction to separate from the center of the region in which the microlenses constituting the first group region are arranged.

5. The sensor according to claim 1, wherein the microlens having the second shape has a teardrop shape.

6. The sensor according to claim 1, wherein the pixel further includes an interlayer lens, a color filter, and a lightguide, and
centers of the interlayer lens and the color filter are shifted from a center of the lightguide.

7. The sensor according to claim 1, wherein centers of the bottom surface of the microlenses having the first shape and the second shape are shifted from centers of photoelectric conversion elements of the pixels corresponding to the microlenses.

8. The sensor according to claim 7, wherein a shift amount increases toward a peripheral portion of the image sensor.

9. An image pickup apparatus comprising:
a solid-state image sensor including a plurality of pixels including photoelectric conversion elements arranged in matrix and an microlens array in which a plurality of microlenses respectively corresponding to the plurality of pixels are arranged,
wherein a first group including microlenses each having a first shape and a second group including microlenses each having a second shape different from the first shape are arranged in the microlens array, and
a center of a region in which the microlenses constituting the first group is shifted from a center of an effective pixel region of the image sensor, and a region in which the microlenses constituting the second group are arranged includes two portions arranged to sandwich the entire first group; and
a processing unit configured to process a signal output from the solid-state image sensor.
